(19) United States
(12) Patent Application Publication
(10) Pub. No.: US 2008/0246101 A1
(43) Pub. Date: Oct. 9, 2008

(54) METHOD OF POLY-SILICON GRAIN STRUCTURE FORMATION

(75) Inventors: Ming Li, Cupertino, CA (US); Yi Ma, Santa Clara, CA (US); R. Suryanarayanan Iyer, Edina, MN (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS INC.

(21) Appl. No.: 11/696,947

(22) Filed: Apr. 5, 2007

(51) Int. Cl. H01L 29/78; H01L 21/4763

(52) U.S. Cl. 257/412; 438/585; 257/E29.255; 257/E21.495

(57) ABSTRACT

A method for forming a poly-crystalline silicon film on a substrate by positioning a substrate within a processing chamber, heating the processing chamber to a first temperature between about 640° C. and about 720° C., stabilizing a deposition pressure between about 200 Torr and about 350 Torr, introducing a silicon precursor into the processing chamber to deposit a silicon film comprising an amorphous or hemisphere grain film, and heating the processing chamber to a second temperature between about 700° C. and about 750 C.° to anneal the amorphous or hemisphere grain film into a poly-crystalline nano-crystalline grain film.

### BACKGROUND OF THE INVENTION

1. Field of the Invention

Embodiments of the present invention relate to the field of semiconductor processing and more specifically, to a method and apparatus for controlling the crystal structure of a silicon film.

2. Description of the Related Art

Poly-crystalline silicon films formed by Low-Pressure Chemical Vapor Deposition (LPCVD) have wide use in the fabrication of integrated circuits such as microprocessors and memory devices. Poly-crystalline silicon film deposition processes require adequate physical, chemical, and production-worthy properties. For example, production-worthy properties include uniform thickness and composition for the polysilicon film (e.g., within substrate and substrate-to-substrate), low particulate and chemical contamination, and high throughput for manufacturing. However, in order to form the poly-crystalline silicon films having production-worthy properties via a conventional LPCVD process, the processing temperature is in a narrow temperature range, typically within a 5° C. to 10° C. temperature window. Therefore, there exists a need for a method of forming a poly-crystalline silicon film over a wider range of temperatures.

### SUMMARY OF THE INVENTION

Embodiments of the present invention generally provide a method for forming a poly-crystalline silicon film on a substrate. In one embodiment, the method comprises positioning a substrate within a processing chamber, heating the processing chamber to a first temperature between about 640° C. and about 720° C., stabilizing a deposition pressure between about 200 Torr and about 350 Torr, introducing a silicon precursor into the processing chamber to deposit a silicon film comprising an amorphous or hemisphere grain film, and heating the processing chamber to a second temperature between about 700° C. and about 750 C.° to anneal the amorphous or hemisphere grain film into a poly-crystalline nano-crystalline grain film.

In a further embodiment, the method comprises positioning within a processing chamber a substrate having a gate dielectric disposed on the substrate, heating the processing chamber to a first temperature between about 640° C. and about 720° C., stabilizing a deposition pressure between about 200 Torr and about 350 Torr, introducing a silicon precursor, a carrier gas, and hydrogen into the processing chamber to deposit a silicon film comprising an amorphous or hemisphere grain film, and heating the processing chamber to a second temperature between about 700° C. and about 750 C.° to anneal the amorphous or hemisphere grain film into a poly-crystalline nano-crystalline grain film.

In a further embodiment, an integrated circuit is provided. The integrated circuit comprises a gate dielectric layer disposed on a substrate and a poly-crystalline silicon film comprising nano-crystal grains having an average grain diameter between about 60 Å and about 100 Å and surface roughness of about 30 Å or less.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a cross-sectional side view of a processing chamber according to an embodiment of the invention.

FIG. 2 illustrates a block diagram of one embodiment of a process for forming a poly-crystalline silicon film on a substrate.

FIGS. 3A-3B illustrate a cross section of a substrate and the formation of poly-crystalline films thereon according to an embodiment of the invention.

FIG. 4 is a plot of XRD data for a deposited silicon film before and after annealing, according to an embodiment of the invention.

FIG. 5 is a plot of grain size versus process silane flow rate according to an embodiment of the invention.

FIG. 6 is a plot of grain size versus process pressure according to an embodiment of the invention.

### DETAILED DESCRIPTION

Embodiments of the present invention relate to controlling the crystal structure of a deposited silicon film. In particular, the embodiments relate to forming poly-crystalline nano-crystalline grain films on a substrate.

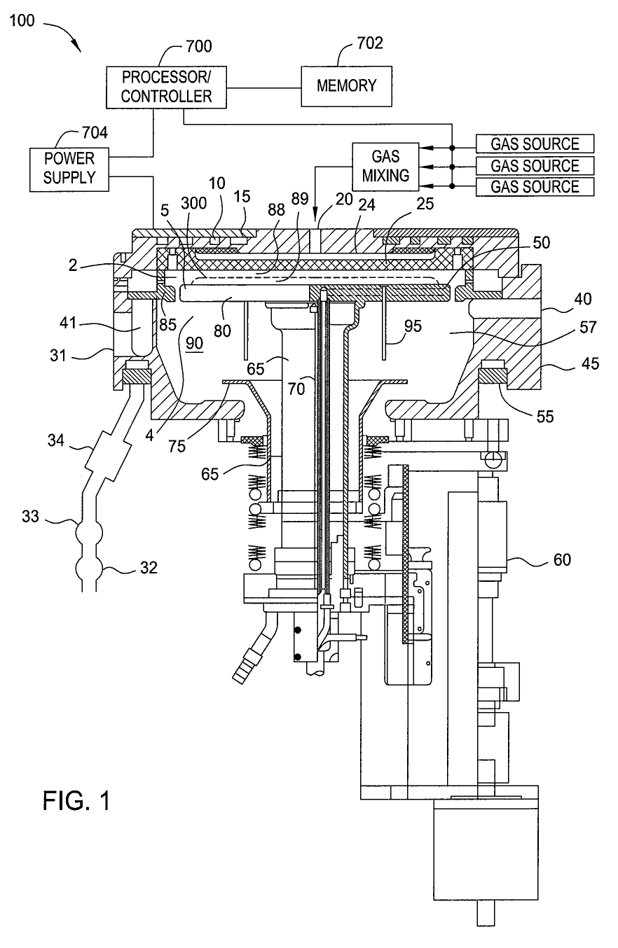

FIG. 1 illustrates one embodiment of an apparatus that may be used to practice embodiments of the present invention. An example of a chamber that may be used is the POLYGEN CENTURA® chemical vapor deposition (CVD) chamber, commercially available from Applied Materials, Inc. of Santa Clara, Calif. In one particular embodiment, the apparatus may be a LPCVD chamber 100. The LPCVD chamber 100 illustrated in FIG. 1 is constructed of materials to maintain, in one embodiment, a deposition chamber pressure between about 200 Torr and about 350 Torr and a deposition chamber temperature between about 600° C. and about 800° C. For the purpose of illustration, LPCVD chamber 100 may have a chamber volume of about 5-6 liters. FIG. 1 illustrates the inside of process chamber body 45 in a “substrate-process” position. A substrate 300 is indicated in dashed lines to indicate its location in LPCVD chamber 100. In one embodiment, LPCVD chamber 100 is adapted to hold one substrate only (i.e., a single substrate chamber). Chamber body 45 may also be sized to accommodate a substrate having a diameter between about 200 mm and about 400 mm.

A chamber body 45 defines reaction chamber 90 in which the thermal decomposition of a process gas or gases takes place to form a nano-crystal silicon film on substrate 300. Chamber body 45 is constructed, in one embodiment, of aluminum and has a passage 55 for water to be pumped therethrough, for example, within the chamber walls, to isolate the reaction area around substrate 300 and prevent deposition on the inside walls of chamber 45. In one embodiment, LPCVD chamber 100 may be a “cold-wall” reaction chamber. Resident in reaction chamber 90 is resistive heater 80 including susceptor 5 supported by shaft 65. Susceptor 5 has a surface area sufficient to support a substrate such as a semiconductor substrate 300 (shown in dashed lines). Substrate 300 may be any surface, generated when making an integrated circuit, upon which a conductive layer may be formed. Substrate 300 thus may include, for example, active and passive devices that are formed on a silicon substrate such as transistors, capacitors, resistors, diffused junctions, gate electrodes, local interconnects, etc.

FIG. 1 also illustrates a cross-sectional view of a portion of heater 80, including a cross-section of the body of susceptor 5 and a cross-section of shaft 65. In this illustration, FIG. 1 illustrates the body of susceptor 5 having two heating elements formed therein, first heating element 50 and second heating element 57. Each heating element (e.g., heating element 50 and heating element 57) is made of a material with thermal expansion properties similar to the material of susceptor 5. In one embodiment, the material for susceptor 5 may be molybdenum (Mo), or other heating elements known in the art. In one embodiment, first and second heating elements 50, 57 include a thin layer of molybdenum material in a coiled configuration. The dual heater system of LPCVD chamber 100 provides the advantage of allowing for precise control of the deposition temperature for nano-crystal silicon. In an alternative embodiment, LPCVD chamber 100 may include lamp heaters instead of the resistive type heaters described above with respect to heating elements 50 and 57.

The deposition environment provided by LPCVD chamber 100 allows for the precise controlling of temperature and pressure. In one embodiment, heater 80 with heating elements 50 and 57 allow for precise temperature control and stability. The passage of process gas through blocker plate 24 and perforated face plate 25 provides the advantage of uniform gas distribution towards substrate 300. In one embodiment, materials for reaction chamber 90 are compatible with the process gases and other chemicals, such as cleaning chemicals (e.g., nitrogen trifluoride, NF₃) that may be introduced into reaction chamber 90.

The exposed surfaces of heater 80 may be comprised of a variety of materials provided that the materials are compatible with the process. For example, susceptor 5 and shaft 65 of heater 80 may be comprised of similar aluminum nitride material. Alternatively, the surface of susceptor 5 may be comprised of high thermally conductive aluminum nitride materials (on the order of about 95% purity with a thermal conductivity from about 140 W/mK, in one embodiment) while shaft 65 is comprised of a lower thermally conductive aluminum nitride. In one embodiment, susceptor 5 of heater 80 may be coupled to shaft 65 through diffusion bonding or brazing, because this type of coupling may withstand the environment of reaction chamber 90.

In FIG. 1, second heating element 57 is formed in a plane of the body of susceptor 5 that is disposed inferior (relative to the surface of susceptor in the figure) to first heating element 50. First heating element 50 and second heating element 57 are separately coupled to power terminals. The power terminals extend in an inferior direction as conductive leads through a longitudinally extending opening through shaft 65 to a power source that supplies the requisite energy to heat the surface of susceptor 5. Extending through openings in chamber lid are two pyrometers, first pyrometer 10 and second pyrometer 15. Each pyrometer provides data about the temperature at the surface of susceptor 5 (or at the surface of a substrate on susceptor 5). Thermocouple 70 may be positioned in the cross-section of heater 80. Thermocouple 70 extends through the longitudinally extending opening through shaft 65 to a point just below the superior or top surface of susceptor 5.

Process gas may enter the otherwise sealed reaction chamber 90 through gas distribution port 20 in a top surface of chamber lid 30 of chamber body 45. The process gas may then go through blocker plate 24 to distribute the gas about an area consistent with the surface area of a substrate. Thereafter, the process gas may be distributed through perforated face plate 25 located above resistive heater 80 and coupled to chamber lid 30 inside reaction chamber 90. In one embodiment, the combination of blocker plate 24 with face plate 25 creates a uniform distribution of process gas near a top surface of substrate 300.

As illustrated, substrate 300 may be placed in reaction chamber 90 on susceptor 5 of heater 80 through entry port 40 in a side portion of chamber body 45. To accommodate a substrate for processing, heater 80 is lowered so that the surface of susceptor 5 is below entry port 40. In one embodiment, with a robotic transfer mechanism, substrate 300 may be loaded by way of, for example, a transfer blade (not shown) into reaction chamber 90 onto the superior surface of susceptor 5. Once loaded, entry 40 is sealed and heater 80 is advanced in a superior (e.g., upward) direction toward face plate 25 by lifter assembly 60 that is, for example, a step motor. The advancement stops when the substrate 300 is a short distance (e.g., 400-700 mils) from face plate 25. In the substrate-process position of FIG. 1, reaction chamber 90 is effectively divided into two zones, a first zone 2 above the superior surface of susceptor 5 and a second zone 4 below the inferior surface of susceptor 5.

With substrate 300 disposed within reaction chamber 90, first zone 2 includes an area 88 above substrate 300 such that nano-crystal silicon film/layer formation is confined to an upper surface (i.e., the surface below perforated face plate 25). That is, nano-crystal silicon film deposition is limited to one side of substrate 300. In one embodiment, area 88 defines a partial pressure area in reaction chamber 90 (i.e., (flow rate of precursor/total flow)×chamber pressure) for a gas source such as a silicon precursor. In an alternative embodiment, nano-crystal silicon formation may be accomplished in both the first and second zones for silicon film deposition on both sides of substrate 300. Accordingly, area 88 and area 89, corresponding to the top and bottom surfaces of substrate 300, defines the partial pressure area for dual sided silicon film deposition.

At this point, process gas controlled by a gas panel flows into reaction chamber 90 through gas distribution port 20, through blocker plate 24 and perforated face plate 25. Process gas may thermally decompose to form a film on the substrate. At the same time, an inert bottom-purge gas, e.g., nitrogen, may be introduced into the second chamber zone to inhibit film formation in that zone. In a pressure controlled system, the pressure in reaction chamber 90 may be established and maintained by a pressure regulator or regulators (not shown) coupled to reaction chamber 90. In one embodiment, for example, the pressure is established and maintained by baratron pressure regulator(s) coupled to chamber body 45 as known in the art. In one embodiment, the baratron pressure regulator(s) maintains pressure at a level between about 200 Torr to about 350 Torr and a temperature between about 640° C. and 720° C. for the deposition of nano-crystal silicon on substrate 300.

Residual process gas may be pumped from reaction chamber 90 through pumping plate 85 to a collection vessel at a side of chamber body 45 (vacuum pumpout 31). Pumping plate 85 may create two flow regions resulting in a gas flow pattern that forms a poly-crystalline silicon layer on substrate 300.

Pump 32 disposed exterior to apparatus may provide vacuum pressure within pumping channel 41 to draw both the process and purge gases out of the reaction chamber 90 through vacuum pump-out 31. The gas is discharged from reaction chamber 90 along a discharge conduit 33. The flow rate of the discharge gas through channel 41 may be controlled by a throttle valve 34 disposed along conduit 33. In one embodiment, the pressure within processing reaction chamber 90 is monitored with sensors (not shown) and controlled by varying the cross-sectional area of conduit 33 with throttle valve 34. Preferably, a controller or processor (also not shown) receives signals from the sensors that indicate the chamber pressure and adjusts throttle valve 34 accordingly to maintain the desired pressure within reaction chamber 90.

Once processing of substrate 300 is complete, reaction chamber 90 may be purged, for example, with an inert gas, such as nitrogen. After processing and purging, heater 80 is advanced in an inferior direction (e.g., lowered) by lifter assembly 60. As heater 80 is moved, lift pins 95, having an end extending through openings or throughbores in a surface of susceptor 5 and a second end extending in a cantilevered fashion from an inferior (e.g., lower) surface of susceptor 5, contact lift plate 75 positioned at the base of reaction chamber 90. In one embodiment, lift plate 75 remains at a substrate-process position. As heater 80 continues to move in an inferior direction through the action of assembly 60, lift pins 95 remain stationary and ultimately extend above the susceptor or top surface of susceptor 5 to separate a processed substrate 300 from the surface of susceptor 5. The surface of susceptor 5 is moved to a position below entry port 40.

Once a processed substrate 300 is separated from the surface of susceptor 5, the transfer blade of a robotic mechanism may be inserted through opening 40 beneath the heads of lift pins 95 and substrate 300 is supported by lift pins 95. Next, lifter assembly 60 inferiorly moves (e.g., lowers) heater 80 and lift plate 75 to a “substrate load” position. By moving lift plates 75 in an inferior direction, lift pins 95 are also moved in an inferior direction, until the surface of the processed substrate 300 contacts the transfer blade (not shown). The processed substrate 300 may then be removed through entry port 40 by, for example, a robotic transfer mechanism that removes substrate 300 and transfers substrate 300 to the next processing step. A second substrate (not shown) may then be loaded into reaction chamber 90. The steps described above are generally reversed to bring substrate 300 into a process position.

Single substrate LPCVD chamber 100 may include a processor/controller 700 and a memory 702, such as a hard disk drive. The processor/controller 700 may include a single board (SBC) analog and digital input/output boards, interface boards and stepper motor controller board and is coupled to power supply 704. Processor/controller 700 controls all activity of LPCVD chamber 100. Controller 700 executes system control software, which is a computer program stored in a computer readable medium such as memory 702. The computer readable medium includes any mechanism that provides (i.e., stores and/or transmits) information in a form accessible by a machine (i.e., a computer, network device, personal digital assistant, manufacturing tool such as a single substrate deposition chamber, any device with a set of one or more processors, etc.). For example, a computer readable medium includes recordable/non-recordable media (e.g., read only memory (ROM); random access memory (RAM); magnetic disk storage media; optical storage media; flash memory devices, etc.), as well as electrical, optical, acoustical or other form of propagated signals (e.g., carrier waves, infrared signals, digital signals, etc.).

The computer program may include sets of instructions that dictate the timing, mixture of gases, chamber pressure, heater temperature, power supply (e.g., 704), susceptor position, and other parameters of the nano-crystal silicon deposition process. The computer program code can be written in any conventional computer readable programming language such as 68000 assembly language, C, C++, Pascal, Fortran, or others. Subroutines for carrying out process gas mixing, pressure control, and heater control may be stored within memory 702. Memory 702 also stores process parameters such as process gas flow rates and compositions, temperatures, and pressures necessary to form a poly-crystalline silicon film. In one embodiment, LPCVD chamber 100 includes in memory 702 instructions and process parameters for providing a silicon source gas and a carrier gas mix into reaction chamber 90, heating the susceptor 5 to a temperature between about 640° C. and about 750° C., and generating a pressure between about 200 Torr to about 350 Torr within reaction chamber 90 so that a poly-crystalline silicon film may be deposited by thermal chemical vapor deposition onto substrate 300.

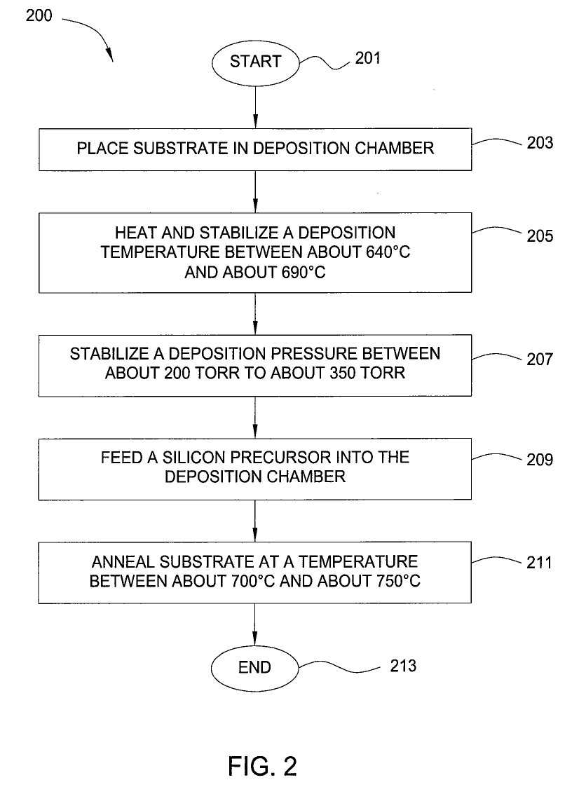

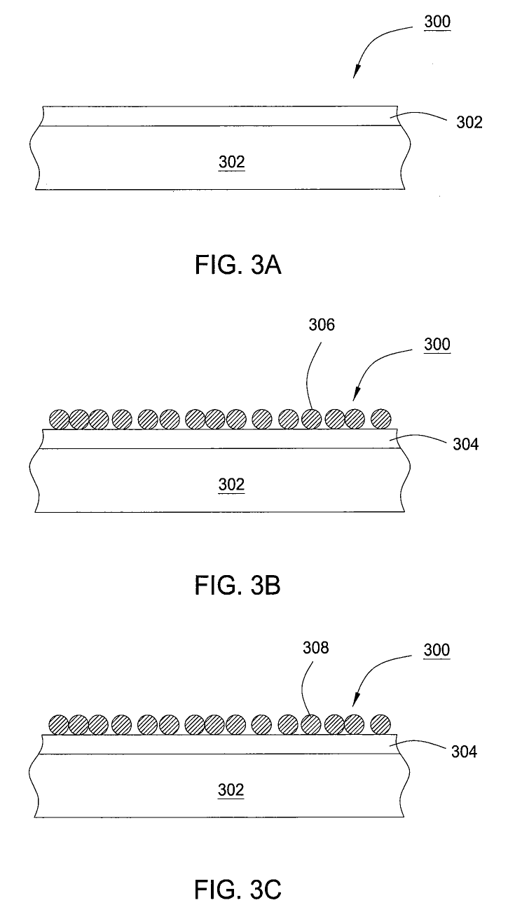

FIG. 2 illustrates a block diagram of one embodiment of a process 200 for forming a poly-crystalline silicon film on a substrate, with respect to the single substrate LPCVD chamber (e.g., 100) of FIG. 1. The method starts in step 201 and continues to step 203 in which a substrate or substrate (e.g., substrate 300) is placed in deposition chamber (e.g., single substrate deposition chamber 90). In one embodiment of the present invention, where the deposited poly-crystalline silicon film is to be used as a gate electrode for a transistor of a semiconductor integrated circuit, the substrate may be a doped silicon substrate 302 having a gate dielectric layer 304, such as silicon oxide or silicon oxynitride formed thereon as illustrated in FIG. 3A. Examples of dopants include, but are not limited to, germane (GeH₄), phosphine (PH₃), and diborane (B₂H₆). In one embodiment, the silicon precursor gas may include a dopant in situ so that a separate doping procedure is not required (i.e., the dopant is delivered with the carrier gas). If the poly-crystalline silicon film is used as an interconnect or capacitor electrode, then the poly-crystalline silicon film may be formed over an interlayer dielectric 304 formed over a doped silicon substrate 302. The substrate is transferred into the chamber by a transfer blade. A heater (e.g., heater 80) is then raised from the substrate load position to the substrate process position as shown in FIG. 1.

In step 205, the desired deposition temperature is obtained and stabilized in the chamber. In one embodiment, the deposition temperature of the chamber may be between about 640° C. and about 720° C., preferably between about 660° C. and about 690° C. In step 207, the desired deposition pressure is obtained and stabilized in the chamber. In one embodiment, the deposition pressure may be between about 200 Torr to about 350 Torr, preferably, between about 30 Torr and about 350 Torr. Steps 205 and 207 may be performed in a reverse order, in an overlapping order, in a simultaneous order, or in any combination of orders. A flowing carrier gas or dilution gas may be introduced into the chamber. In one embodiment, the carrier or dilution gas may be nitrogen or argon.

In step 209, a silicon source (i.e., precursor) is fed into the chamber with a carrier gas (e.g., nitrogen, helium, argon) with a partial pressure.

The silicon source and carrier gas are fed into the chamber to deposit a silicon film 306 on substrate 300 as shown in FIG. 3B. Silicon film 306 may be deposited as amorphous or hemisphere grain (HSG) films. Additionally, crystal nuclei may be formed in film 306. The flow of the silicon source is limited to area 88 above the top surface of substrate 300 for deposition of silicon on one side of substrate 300. In one embodiment of the present invention, the silicon source may be a gas such as silane (SiH₄), or alternatively other silicon source gases such as disilane (Si₂H₆), trisilane (Si₃H₈), and bis-tertiarybutylamino silane (BTBAS, (C₈H₂₂N₂Si)). In one embodiment, the carrier gas may be a mixture that includes H₂ and an inert gas (e.g., nitrogen, helium, argon). In one example, the silicon source is fed into the chamber between about 50 standard cubic centimeters per minute (sccm) and about 150 sccm, while the deposition temperature (i.e., the temperature of heater 80) in chamber 90 is maintained at a steady temperature between about 640° C. and about 690° C. and a deposition pressure of about 150 Torr and about 350 Torr.

In one embodiment, a dopant precursor gas may also be introduced into the chamber to deposit a doped silicon film 306. Any suitable dopant precursor may be used, such as BCl₃ for boron doping and PH₃ for phosphorous doping. The dopant precursor flow may be between about 20 sccm and about 130 sccm.

In an alternative embodiment, the precursor gas may be fed into reaction chamber 90 on both sides of substrate 300 for silicon film formation (i.e., simultaneous deposition of silicon through areas 88 and 89 of chamber 90).

The thermal energy from a susceptor (e.g., susceptor 5) and substrate (e.g., substrate 300 or substrate 302) disposed within the chamber causes the silicon source gas to thermally decompose and deposit an amorphous or HSG silicon film 306 on gate dielectric or interlayer dielectric 304 disposed above silicon substrate 302 as shown in FIG. 3B.

In one embodiment of the present invention, the deposition pressure, temperature, and process gas flow rates and concentration are chosen so that the amorphous or HSG silicon film is deposited at a deposition rate in the range of about 5 Å/min (Angstroms per minute) to about 15 Å/min. The deposition rate may depend on the process chemistry, temperature, or pressure. For example, silane may be deposited at a rate of about 5 Å/min based on a deposition temperature between about 640° C. and about 690° C., a deposition pressure of about 150 Torr and about 350 Torr, and a partial pressure of about 0.5 Torr and about 3.5 Torr. The process gas mix is continually fed into the chamber until an amorphous or HSG silicon film 306 of a desired thickness is formed.

Step 311 is an annealing step in which substrate 300 is heated to a temperature between about 700° C. and about 750° C., preferably, between about 720° C. and about 740° C. An inert gas (e.g., nitrogen, helium, argon) may be flowed in to the chamber during the annealing. As the temperature of substrate 300 rises, the amorphous or HSG silicon film 306 obtain kinetic energy to convert silicon film 306 into a poly-crystalline silicon film 308 of nano-crystal grains (NCG), as depicted in FIG. 3C. Although not bound by this theory, the anneal temperature provides sufficient kinetic energy for nano-crystal grains to be grown around the crystal nuclei of film 306. Furthermore, the energy the Si atoms obtain through the annealing enables the atoms to migrate, so that the particles obtain a surface roughness of less than about 30 Å. Typically the roughness of a one step deposition HSG particle is about 55 Å.

Step 311 may be performed in the same substrate processing chamber as the LPCVD process, such as in the single substrate LPCVD chamber 100 of FIG. 1. Alternatively, annealing step 311 may be performed in a separate annealing chamber, such as in an RTP chamber such as the RADIANCE CENTURA® system, commercially available from Applied Materials, Inc, in Santa Clara, Calif. The process ends with step 213.

### EXAMPLES

Polycrystalline NCG films were prepared in these examples, unless otherwise stated, according to process 200 in a POLYGEN CENTURA® CVD chamber on a silicon substrate having an about 25 Å silicon oxide gate dielectric layer.

### Example 1

Amorphous silicon was deposited over the silicon oxide gate dielectric layer at a temperature of about 680° C. and at a chamber pressure of about 275 Torr. A gas mixture of disilane (90 sccm), nitrogen (6 standard liters per minute, or mls), and hydrogen (2 mls) was introduced to the chamber until a film with a 1000 Å was formed. The substrate was then heated in the same chamber to a temperature of about 720° C. for about 2 minutes in nitrogen for an in-situ annealing process.

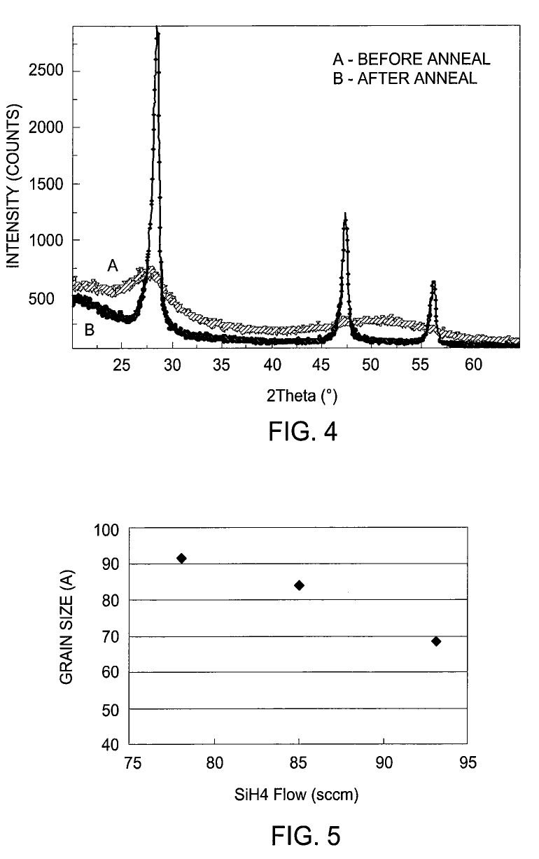

FIG. 4 shows the XRD data for Example 1 before and after annealing. As seen in FIG. 4, before the annealing process the deposited film is amorphous and after annealing, the peak at 2 theta of 47.5° indicates silicon having a <220> orientation which is representative of a poly-crystalline component.

The annealing step also alters the stress type of the deposited film. After the deposition, but before annealing, the deposited film has a compressive stress of about −2.1*10⁹ dynes/cm². After the annealing the stress changes to a tensile stress of about −1.5*10⁹ dynes/cm². The same deposited film annealed at 740° C., instead of 720° C., has a tensile stress of about 3*10⁹ dynes/cm².

### Example 2

FIG. 5 shows that grain size of the poly-crystalline NCG can be controlled by the process conditions, such as silicon precursor flow rate. Three experiments were performed using three different flow rates of silane were performed. The processing conditions were the same for all three runs except for the differing silane flow rates. The deposition temperature was about 680° C. and the chamber pressure was about 275 Torr. A gas mixture of silane, nitrogen (6 mls), and hydrogen (2 mls) was introduced to the chamber until a film with a 1000 Å was formed. The substrate was then heated in the same chamber to a temperature of about 720° C. for about 2 minutes in nitrogen for an in-situ annealing process. The grain size decreases in diameter as the silane flow rate increases. A silane flow rate of about 78 sccm results, under these conditions, in a grain diameter of about 92 Å. At about 85 sccm a grain diameter of about 85 Å results, and at about 93 sccm a grain diameter of about 69 Å results.

### Example 3

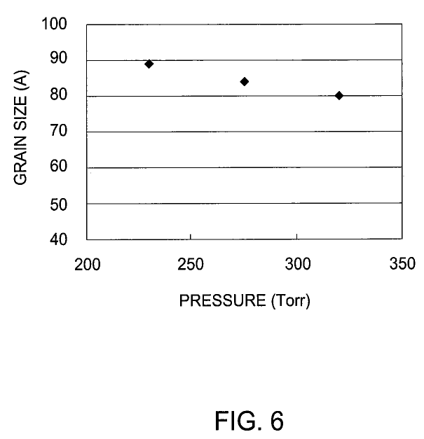

FIG. 6 shows that grain size of the poly-crystalline NCG can be controlled by the process conditions, such as chamber pressure. Three experiments were performed at three different chamber pressures. The processing conditions were the same for all three runs except for the differing chamber pressures. The deposition temperature was about 680° C. a. A gas mixture of silane (90 sccm), nitrogen (6 mls), and hydrogen (2 mls) was introduced to the chamber until a film with a 1000 Å was formed. The substrate was then heated in the same chamber to a temperature of about 720° C. for about 2 minutes in nitrogen for an in-situ annealing process. The grain size decreases in diameter as the chamber pressure increases. A chamber pressure of about 225 Torr results, under these conditions, in a grain diameter of about 89 Å. At about 275 Torr grain diameter of about 83 Å results, and at about 325 Torr a grain diameter of about 80 Å results.

### Example 4

Amorphous silicon was deposited over the silicon oxide gate dielectric layer of two substrates at a temperature of about 720° C. and at a chamber pressure of about 275 Torr. A gas mixture of silane (250 sccm), nitrogen (6 mls), and hydrogen (2 mls) was introduced for a deposition time of about 21 seconds. For first substrate, the chamber was pumped down immediately following the film deposition. Elipsometry measurements were performed, showing a refractive index of about 2.95 and a deposited film thickness of about 142 Å. Because crystalline silicon has a refractive index of about 3.8 and amorphous a refractive index of about 4.4, a refractive index of about 2.95 indicates a rough surface HSG phase film, as the HSG film includes air or gas filled voids within the HSG film, thus lowering the refractive index. For the second wafer, an annealing step for about 18 seconds was performed after the deposition. After the deposition, the silane flow was shut off, but the inert gas flows, temperature and chamber pressure were maintained for the about 18 seconds annealing. The measured refractive index of the annealed poly-crystalline film is about 3.86 and measured roughness is about 18 Å by elipsometry. The grain size of the annealed grains is about 90 Å as determined by XRD analysis.

### Example 5

A phosphorous doped silicon film was deposited over a 1000 Å silicon oxide gate dielectric layer at a temperature of about 720° C. and at a chamber pressure of about 275 Torr. A gas mixture of disilane (80 sccm), phosphine (60 sccm), nitrogen (6 mls), and hydrogen (2 mls) was introduced to the chamber for about 16 seconds. The poly-crystalline NCG film was determined by ellipsometry to have an about 500 Å thickness. X-ray diffraction indicated an average grain size diameter to be about 90 Å. X-ray fluorescence indicated the P dopant concentration to be about 1.9*10²⁰ atoms/cm³.

While the foregoing is directed to embodiments of the present invention, other and further embodiments of the invention may be devised without departing from the basic scope thereof, and the scope thereof is determined by the claims that follow.

1. A method for forming a poly-crystalline silicon film on a substrate, comprising
positioning a substrate within a processing chamber;
heating the processing chamber to a first temperature between about 640° C. and about 720° C.;
stabilizing a deposition pressure between about 200 Torr and about 350 Torr;
introducing a silicon precursor into the processing chamber to deposit a silicon film comprising an amorphous or hemisphere grain film; and
heating the processing chamber to a second temperature between about 700° C. and about 750 C.° to anneal the amorphous or hemisphere grain film into a poly-crystalline nano-crystalline grain film.

2. The method of claim 1, further comprising introducing hydrogen gas into the processing chamber to deposit the silicon film.

3. The method of claim 2, further comprising introducing a carrier gas into the processing chamber with the silicon precursor.

4. The method of claim 3, wherein the silicon precursor has a flow rate between about 75 sccm and about 250 sccm.

5. The method of claim 4, wherein the silicon precursor is selected from at least one of silane, disilane, trisilane, and bis-tertiarybutylamino silane.

6. The method of claim 7, wherein the carrier gas comprises at least one of nitrogen and argon.

7. The method of claim 1, wherein the first temperature is between about 660° C. and about 690° C.

8. The method of claim 1, wherein the second temperature is between about 720° C. and about 740° C.

9. The method of claim 1, wherein annealing is performed in separate processing chamber.

10. The method of claim 1, wherein the silicon film is deposited on a gate dielectric layer.

11. The method of claim 10, wherein the gate dielectric layer comprises silicon oxide.

12. A method for forming a poly-crystalline silicon film on a substrate, comprising
positioning within a processing chamber a substrate having a gate dielectric disposed on the substrate;
heating the processing chamber to a first temperature between about 640° C. and about 720° C.;
stabilizing a deposition pressure between about 200 Torr and about 350 Torr;
introducing a silicon precursor, a carrier gas, and hydrogen into the processing chamber to deposit a silicon film comprising an amorphous or hemisphere grain film; and
heating the processing chamber to a second temperature between about 700° C. and about 750 C.° to anneal the amorphous or hemisphere grain film into a poly-crystalline nano-crystalline grain film.

13. The method of claim 12, wherein the silicon precursor has a flow rate between about 75 sccm and about 250 sccm.

14. The method of claim 12, wherein the silicon precursor is selected from at least one of silane, disilane, trisilane, and bis-tertiarybutylamino silane.

15. The method of claim 12, wherein the first temperature is between about 660° C. and about 690° C.

16. The method of claim 12, wherein the second temperature is between about 720° C. and about 740° C.

17. The method of claim 12, wherein the gate dielectric layer comprises silicon oxide.

18. An integrated circuit, comprising:
a gate dielectric layer disposed on a substrate; and
a poly-crystalline silicon film comprising nano-crystal grains having an average grain diameter between about 60 Å and about 100 Å and surface roughness of about 30 Å or less.

19. The integrated circuit of claim 18, wherein the poly-crystalline silicon film has a tensile stress between about −1.5*10⁹ dynes/cm² and about 3*10⁹ dynes/cm².

20. The integrated circuit of claim 19, wherein the gate dielectric layer comprises silicon oxide.
